(19) United States
(12) Patent Application Publication
(10) Pub. No.: US 2025/0293693 A1
(43) Pub. Date: Sep. 18, 2025

(54) SEMICONDUCTOR DEVICE AND SEMICONDUCTOR SYSTEM INCLUDING THE SAME

(71) Applicant: SAMSUNG ELECTRONICS CO., LTD., Suwon-si (KR)

(72) Inventors: Jaegeun SONG, Suwon-si (KR); Sungsik KANG, Suwon-si (KR); Chang Ki KWON, Suwon-si (KR); Gwangwon LEE, Suwon-si (KR); Ilho JUNG, Suwon-si (KR); Kwanyeob CHAE, Suwon-si (KR)

(73) Assignee: SAMSUNG ELECTRONICS CO., LTD., Suwon-si (KR)

(21) Appl. No.: 18/882,190

(22) Filed: Sep. 11, 2024

(30) Foreign Application Priority Data
Mar. 18, 2024 (KR) 10-2024-0037078

(51) Int. Cl. H03L 7/081; G05F 3/26; G11C 7/10; H03K 3/03

(52) U.S. Cl. CPC H03L 7/0816; G05F 3/262; H03K 3/0315; G11C 7/10

(57) ABSTRACT

A semiconductor device may include: an amplifier circuit biased by a reference current or a reference voltage and configured to amplify an input signal; a process monitoring circuit configured to output a control code signal to compensate a manufacturing process deviation of the semiconductor device; and a bias circuit configured to receive the control code signal and to change the reference current or the reference voltage based on the control code signal.

### CROSS-REFERENCE TO RELATED APPLICATION

This application claims priority to and the benefit of Korean Patent Application No. 10-2024-0037078, filed in the Korean Intellectual Property Office on Mar. 18, 2024, the entire contents of which are incorporated herein by reference.

### BACKGROUND

The present disclosure relates to a semiconductor device and a semiconductor system including the same. Semiconductor devices use a bias circuit that stably generates a reference voltage or current in order to control high-level voltages or generate internal power. Representative examples of the bias circuit include a beta multiplier reference circuit and a band-gap reference circuit. Meanwhile, as semiconductor devices become miniaturized and highly integrated, a degree of change in the characteristics of semiconductor devices due to external factors such as process (P), voltage (V), temperature (T), etc. is increasing. Changes in the characteristics of a semiconductor device due to changes in such external factors may have a significant impact on an operation of circuits within the semiconductor device.

### SUMMARY

In view of the concerns above, there is a use for a bias circuit that is insensitive to changes in external factors.

One or more embodiments of the present disclosure attempts to provide a semiconductor device including a bias circuit that generates a reference current or a reference voltage based on characteristics of the semiconductor device according to process variables, and a semiconductor system including the same.

One or more embodiments of the present disclosure attempts to provide a semiconductor device that prevents performance degradation of the semiconductor device due to process variables and a semiconductor system including the same.

According to one or more example embodiments, a semiconductor device may include: an amplifier circuit biased by a reference current or a reference voltage and configured to amplify an input signal; a process monitoring circuit configured to output a control code signal to compensate a manufacturing process deviation of the semiconductor device; and a bias circuit configured to receive the control code signal and to change the reference current or the reference voltage based on the control code signal.

According to one or more example embodiments, a semiconductor device may include: a process monitoring circuit configured to: generate a first signal representing characteristic information based on the characteristic information obtained in an initial state, which is within a predetermined time after a power is applied; and output a digital code signal corresponding to the first signal; a bias circuit configured to generate a bias current or a bias voltage based on a value of a variable resistance changed based on the digital code signal; and a device circuit configured to receive the bias current or the bias voltage.

According to one or more example embodiments, a semiconductor system may include: a first semiconductor device; and a second semiconductor device may include: a receiving circuit configured to receive a signal from the first semiconductor device; and a bias circuit configured to supply different reference currents or reference voltages to the receiving circuit based on a value of a variable resistor that changes in response to characteristics due to a manufacturing process deviation of the second semiconductor device.

According to one or more example embodiments, a semiconductor device may include: an amplifier circuit biased by a reference current or a reference voltage and configured to amplify an input signal; a process monitoring circuit configured to output a control code signal to compensate a temperature change of the semiconductor device; and a bias circuit configured to receive the control code signal and to change the reference current or the reference voltage based on the control code signal, the bias circuit may include a variable resistor whose resistance value changes based on the control code signal to change the reference current or the reference voltage.

### BRIEF DESCRIPTION OF THE DRAWINGS

Embodiments will be more clearly understood from the following detailed description taken in conjunction with the accompanying drawings in which:

FIG. 1 illustrates a schematic block diagram of a semiconductor device according to one or more embodiments;

FIG. 2 illustrates a block diagram of a semiconductor device according to one or more embodiments;

FIG. 3 illustrates a block diagram showing a process monitoring module according to one or more embodiments;

FIG. 4 illustrates a block diagram showing a process monitoring module according to one or more embodiments;

FIG. 5 illustrates a block diagram showing a process monitoring module according to one or more embodiments;

FIG. 6 illustrates a view for describing a lookup table according to one or more embodiments;

FIG. 7 illustrates a block diagram showing a process monitoring module according to one or more embodiments;

FIG. 8 illustrates a block diagram showing a process monitoring module according to one or more embodiments;

FIG. 9A illustrates a view for describing an operation method of a pulse counter according to one or more embodiments;

FIG. 9B illustrates a view for describing an operation method of a pulse counter according to one or more embodiments;

FIG. 10 illustrates a view for describing a lookup table according to one or more embodiments; and

FIG. 11 illustrates a configuration of a semiconductor system according to one or more embodiments.

### DETAILED DESCRIPTION

In the following detailed description, only certain embodiments of the present disclosure have been shown and described, simply by way of illustration. As those skilled in the art would realize, the described embodiments may be modified in various different ways, all without departing from the spirit or scope of the present disclosure.

Accordingly, the drawings and description are to be regarded as illustrative in nature and not restrictive. Like reference numerals designate like elements throughout the specification. In a flowchart described with reference to the drawings, an order of operations may be changed, several operations may be merged, some operations may be divided, and specific operations may not be performed.

In addition, expressions written in the singular may be construed in the singular or plural unless an explicit expression such as “one” or “single” is used. Terms including ordinal numbers such as first, second, and the like will be used only to describe various component and are not to be interpreted as limiting these components. These terms may be used for the purpose of distinguishing one constituent element from other constituent elements.

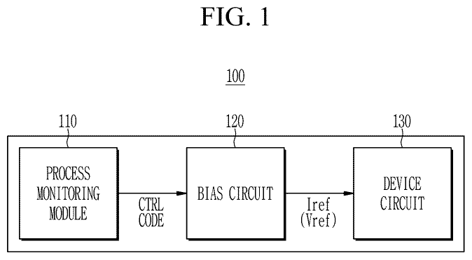

FIG. 1 illustrates a schematic block diagram of a semiconductor device according to one or more embodiments.

In one or more embodiments, the semiconductor device 100 may include a process monitoring module 110 (i.e. process monitoring circuit), a bias circuit 120, and a device circuit 130.

In one or more embodiments, characteristics of the semiconductor device 100 may change due to various external factors. The characteristics of the semiconductor device 100 may be determined according to a process variable, a temperature (T), a voltage (V), etc. Herein, the process variable is a variable for a process (P) of manufacturing the semiconductor device 100, and may include process deviation information related to the semiconductor device 100. In one or more embodiments, the process variable for the semiconductor device 100 may include corner values for P-type/N-type transistors that constitute the semiconductor device 100. The corner value may be determined according to the characteristics of the P-type/N-type transistors constituting the semiconductor device 100. For example, for the P-type/N-type transistor constituting the semiconductor device 100, the P-type transistor may be fast, slow, or nominal, and the N-type transistor may be fast, slow, or nominal. That is, the corner value may be determined according to an operating speed of the semiconductor device 100, which is determined differently depending on the characteristics of the P-type/N-type transistors constituting the semiconductor device 100. In a process where the semiconductor device 100 is mass-produced, the corner value of the semiconductor device 100 may be determined according to the characteristics of cells within the semiconductor device 100. Herein, the corner value is described as a process variable, but the present disclosure is not limited thereto, and various other process variables that affect the characteristics of the semiconductor device may further exist.

In one or more embodiments, the process monitoring module 110 may detect characteristics of transistors within the semiconductor device 100. For example, depending on the characteristics of the P-type/N-type transistors that constitutes the semiconductor device, if both P-type and N-type transistors are fast, the operation speed of the semiconductor device 100 tends to be fast and have high power consumption. Conversely, if both P-type and N-type transistors are slow, the operation speed of the semiconductor device 100 tends to be slow and have low power consumption. Accordingly, the process monitoring module 110 may detect characteristics of the semiconductor device based on the operating speed of transistors within the semiconductor device. In one or more embodiments, the process monitoring module 110 may detect characteristics of transistors constituting the semiconductor device 100, and may control a control code signal CTRL CODE corresponding to the characteristics of the transistors inside the semiconductor device 100. The control code signal CTRL CODE may be a value for controlling the bias circuit 120 that generates a reference current (or reference voltage). The process monitoring module 110 may include, but is not limited to, a delay locked loop circuit DLL, a ZQ calibration circuit, etc.

In one or more embodiments, the semiconductor device 100 may include a bias circuit 120. The bias circuit 120 may generate a reference current Iref or a reference voltage Vref to be provided to the device circuit 130 using a power voltage supplied from the outside. In one or more embodiments, the bias circuit 120 may receive the control code signal CTRL CODE corresponding to the characteristics of the transistors within the semiconductor device 100 from the process monitoring module 110. The bias circuit 120 includes a variable resistor that changes based on the control code signal CTRL CODE, and may generate the reference current Iref or the reference voltage Vref that changes based on a value of the variable resistor. The bias circuit 120 according to one or more embodiments may generate the reference current Iref or the reference voltage Vref that changes depending on the characteristics of the transistors inside the semiconductor device 100 according to the process variables of the semiconductor device 100. The bias circuit 120 according to one or more embodiments may receive the control code signal CTRL CODE indicating the characteristics of the transistors inside the semiconductor device 100 from the process monitoring module 110, thereby generating the reference voltage Vref that reflects the characteristics of the transistors within the semiconductor device 100. As a result, the bias circuit 120 may have characteristics that are strong (insensitive) to process changes. The bias circuit 120 may include, but is not limited to, a beta multiplier reference circuit, a band-gap reference circuit, etc.

In one or more embodiments, the device circuit 130 may receive the reference current Iref or the reference voltage Vref from the bias circuit 120. The device circuit 130 may include an amplifier circuit that is biased by the reference current Iref or the reference voltage Vref and amplifies an input signal. In one or more embodiments, the device circuit 130 may include an analog circuit that uses the reference current Iref or the reference voltage Vref, a digital circuit, an analog and digital circuit such as an analog-to-digital converter or a digital-to-analog converter, or a combination thereof.

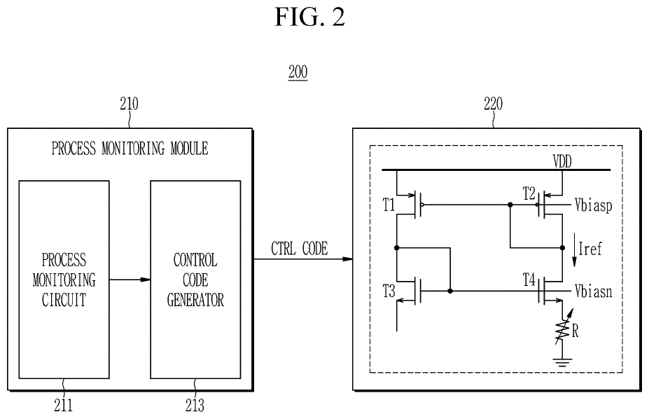

FIG. 2 illustrates a block diagram of a semiconductor device according to one or more embodiments. Specifically, this diagram is for describing a beta multiplier reference circuit as an example of the bias circuit 220 in the semiconductor device 200.

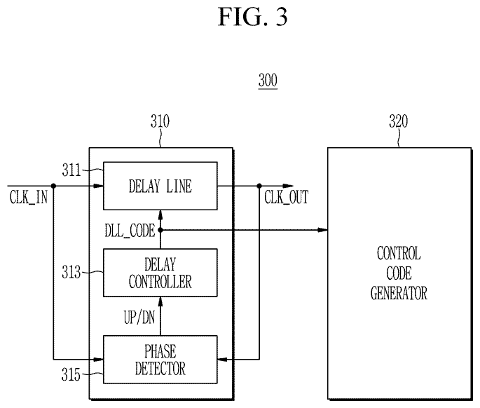

Referring to FIG. 2, the semiconductor device 200 may include a process monitoring module 210 and a bias circuit 220. In an exemplary embodiment, the process monitoring module 210 may include a process monitoring circuit 211 (i.e. process monitoring sub-circuit) and a control code generator 213. The control code generator 213 may generate the control code signal CTRL CODE based on a code signal received from the process monitoring circuit 211. A detailed description of the process monitoring module 210 will be provided later with reference to FIGS. 3 to 10.

In one or more embodiments, the bias circuit 220 may be implemented as a beta multiplier reference circuit. In one or more embodiments, the bias circuit 220 may generate the reference current Iref.

In one or more embodiments, the bias circuit 220 may include two pairs of transistors T1, T2, T3, and T4 connected in a current mirror type. The first transistor T1 and the second transistor T2 may be P-type transistors. The first transistor T1 and the second transistor T2 may each receive a first bias voltage Vbiasp as a gate input. First terminals (e.g., drain terminals) of the first transistor T1 and the second transistor T2 may be connected to a line of a power voltage VDD. A second terminal (e.g., source terminal) of the second transistor T2 may be connected to a gate terminal, so as take a form of a current mirror with the first transistor T1. A second terminal (source terminal) of the first transistor T1 may be connected to a first terminal (e.g., drain terminal) of the third transistor T3, and the second terminal (source terminal) of the second transistor T2 may be connected to a first terminal (e.g., drain terminal) of the fourth transistor T4. The third transistor T3 and fourth transistor T4 may be N-type transistors. The third transistor T3 and the fourth transistor T4 may each receive a second bias voltage Vbiasn as a gate input. The first terminal (drain terminal) of the third transistor T3 may be connected to the gate terminal, so as to take the form of a current mirror with the fourth transistor T4. The second terminal (source terminal) of the third transistor T3 may be connected to a line of a ground voltage VSS. The second terminal (source terminal) of the fourth transistor T4 may be connected to a variable resistor R connected to the line of the ground voltage VSS.

In one or more embodiments, a value of the variable resistor R may change according to the control code signal CTRL CODE. Herein, the control code signal CTRL CODE may be a value corresponding to the characteristics of the transistors inside the semiconductor device 200 according to the process variable. For example, the control code signal CTRL CODE may be a value corresponding to an operation speed of the transistors inside the semiconductor device 200 according to corner values of the P-type/N-type transistors constituting the semiconductor device 200. In one or more embodiments, the value of the variable resistor R may increase or decrease according to the control code signal CTRL CODE. Additionally, the reference current Iref may change depending on a change in the value of the variable resistor R. For example, the value of the variable resistor R may increase according to the control code signal CTRL CODE indicating that the transistors constituting the semiconductor device 200 is fast, and as the variable resistor R increases, a value of the reference current Iref may decrease. Alternatively, the value of the variable resistor R may decrease according to the control code signal CTRL CODE indicating that the transistors constituting the semiconductor device 200 is slow, and as the variable resistor R decreases, a value of the reference current Iref may increases.

Herein, for better understanding and ease of description, an example in which the bias circuit 220 is implemented as a beta multiplier reference circuit has been described, but the present disclosure is not limited thereto, and the bias circuit 220 may be implemented as various bias circuits such as a band-gap reference circuit.

FIG. 3 illustrates a block diagram showing a process monitoring module according to one or more embodiments. Specifically, this diagram is for describing a delay locked loop circuit 310 as an example of a process monitoring circuit within the process monitoring module 300.

Referring to FIG. 3, the process monitoring module 300 may include the delay fixed loop circuit 310 and a control code generator 320. The delay locked loop circuit 310 may be used to synchronize clock signals used within the semiconductor device. For example, when a clock signal is used within the semiconductor device, a time delay (or clock skew) may occur between clock signals due to internal circuits of the semiconductor device. The delay locked loop circuit 310 may be used to compensate for this time delay.

In one or more embodiments, the delay locking loop circuit 310 may generate an output clock CLK_OUT based on an input clock CLK_IN. Specifically, the delay locked loop circuit 310 may generate the output clock CLK_OUT by delaying the input clock CLK_IN. The delay lock loop circuit 310 may perform a delay lock operation such that a phase difference between the input clock CLK_IN and the output clock CLK_OUT is within a predetermined value. The delay lock operation may indicate an operation of controlling a phase difference between the input clock CLK_IN and the output clock CLK_OUT to be within a predetermined value by feeding back the generated output clock CLK_OUT, comparing it with the input clock CLK_IN, and adjusting the delay time.

In one or more embodiments, the delay fixing loop circuit 310 may include a phase detector 315, a delay controller 313, and a delay line 311. The phase detector 315 may detect a phase difference by comparing the input clock CLK_IN and the output clock CLK_OUT, and provide the phase difference to the delay controller 313. The phase difference may be output as an up/down signal UP/DN. For example, if a phase of the output clock CLK_OUT is slower than a phase of the input clock CLK_IN, the phase detector 315 may output a down signal DN indicating that the delay of the delay line 311 needs to be reduced to the delay controller 313 to advance the phase of the output clock CLK_OUT. Alternatively, if a phase of the output clock CLK_OUT is slower than a phase of the input clock CLK_IN, the phase detector 315 may output an up signal UP indicating that the delay of the delay line 311 needs to be increased to the delay controller 313 to delay the phase of the output clock CLK_OUT.

In one or more embodiments, the delay controller 313 may output a signal for adjusting the delay time of the output clock CLK_OUT as an n-bit code signal based on the up/down signal UP/DN received from the phase detector 315. A delay code signal DLL_CODE may increase when the delay controller 313 receives the up signal UP from the phase detector 315, and may decrease when the delay controller 313 receives the down signal DN from the phase detector 315. For example, if the delay code signal DLL_CODE includes 4 bits, an initial value may be an intermediate value such as ‘0110’. Whenever the up signal UP is received from the phase detector 315, the delay controller 313 may output the increasing delay code signal DLL_CODE such as ‘0111’, ‘1000’ . . . to delay the phase of the output clock CLK_OUT

Whenever the down signal DN is received from the phase detector 315, the delay controller 313 may output the decreasing delay code signal DLL_CODE such as ‘0101’, ‘0100’ . . . to advance the phase of the output clock CLK_OUT

In one or more embodiments, the delay line 311 may delay the input clock CLK_IN and output the output clock CLK_OUT. In this case, the delay time may be adjusted according to the delay code signal DLL_CODE. For example, depending on a change in the delay code signal DLL_CODE, the delay time may increase or decrease. The delay time may increase as a value of the delay code signal DLL_CODE increases, and may decrease as the value of the delay code signal DLL_CODE decreases.

In one or more embodiments, the control code generator 320 may receive the delay code signal DLL_CODE from the delay fixing loop circuit 310. The control code generator 320 may receive the delay code signal DLL_CODE from the delay locked loop circuit 310 at regular intervals. The control code generator 320 may detect characteristics of transistors constituting a circuit of the semiconductor device based on the delay code signal DLL_CODE. In one or more embodiments, the control code generator 320 may receive the delay code signal DLL_CODE from the delay fixing loop circuit 310 in an initial state. Herein, the initial state may refer to a period of time after a power is applied to the delay locked loop circuit 310. Alternatively, the initial state may refer to a period of time until a power is applied to the delay locked loop circuit 310 and the delay code signal DLL_CODE is output a predetermined number of times. Alternatively, the initial state may refer to a period of time until a power is applied to the delay locked loop circuit 310 and the delay code signal DLL_CODE is output. However, the present disclosure is not limited thereto. Accordingly, the delay code signal DLL_CODE received by the control code generator 320 may be a value representing characteristic information of the semiconductor device caused by process variables excluding temperature changes and voltage fluctuations that may occur during operation of a semiconductor device. The control code generator 320 may generate a control code for controlling the bias circuit based on the delay code signal DLL_CODE.

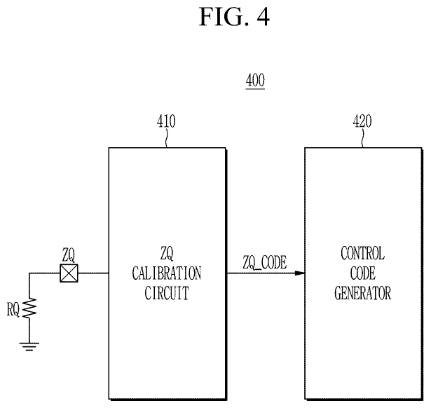

FIG. 4 illustrates a block diagram showing a process monitoring module according to one or more embodiments. Specifically, this diagram is for describing a ZQ calibration circuit 410 as an example of a process monitoring circuit within the process monitoring module 400.

Referring to FIG. 4, the process monitoring module 400 may include the ZQ calibration circuit 410 and a control code generator 420. Generally, a semiconductor device receives various signals transmitted from the outside through an input pad and supplies internal signals to the outside through an output pad. As semiconductor devices become faster, magnitude of signals transmitted between semiconductor devices is gradually decreasing in order to minimize a delay time of signal transmission. However, as the magnitude of the signal decreases, the influence of external noise increases, and signal reflection due to impedance mismatching at an interface becomes more serious. Impedance mismatch occurs due to external noise, changes in process (P), changes in voltage (V), and changes in operating temperature (T). This impedance mismatch may make high-speed data transmission difficult, and output data output from the data output terminal of the semiconductor device may be distorted. Accordingly, the semiconductor device may adjust output impedance through ZQ calibration to solve the above-mentioned problems. The ZQ calibration indicates a process of generating a ZQ code that changes as conditions such as process (P), voltage (V), and temperature (T) change, and impedance matching between external reference resistance RQ and output impedance may be performed using the ZQ code generated as a result of the ZQ calibration.

In one or more embodiments, the ZQ calibration circuit 410 may be connected to a ZQ pad ZQ. The ZQ pad ZQ may be connected to a reference resistor RQ external to the ZQ calibration circuit 410. The ZQ calibration circuit 410 may perform a calibration operation for impedance matching and generate a ZQ code signal ZQ CODE for impedance adjustment.

In one or more embodiments, the control code generator 420 may receive a ZQ code signal ZQ CODE from the ZQ calibration circuit 410. The ZQ code signal ZQ CODE may be a value that reflects changes in the process (P), voltage (V), temperature (T), etc. of the semiconductor device. The control code generator 420 may receive the ZQ code signal ZQ CODE from the ZQ calibration circuit 410 at predetermined cycles. The control code generator 420 may detect the characteristics of the transistors that constitute a circuit of the semiconductor device according to conditions such as process (P), voltage (V), and temperature (T) based on the ZQ code signal ZQ CODE. In one or more embodiments, the control code generator 420 may receive the ZQ code signal ZQ CODE from the ZQ calibration circuit 410 in an initial state. Herein, the initial state may refer to a period of time after a power is applied to the ZQ calibration circuit 410. Alternatively, the initial state may refer to a period of time until a power is applied to the ZQ calibration circuit 410 and the ZQ code signal ZQ CODE is output a predetermined number of times. Alternatively, the initial state may refer to a period of time until a power is applied to the ZQ calibration circuit 410 and the ZQ code signal ZQ CODE is output. However, the present disclosure is not limited thereto. Accordingly, the ZQ code signal ZQ CODE received by the control code generator 420 may be a value representing characteristic information of the semiconductor device caused by process variables excluding temperature changes and voltage fluctuations that may occur during operation of a semiconductor device. The control code generator 420 may generate a control code for controlling the bias circuit based on the ZQ signal ZQ CODE.

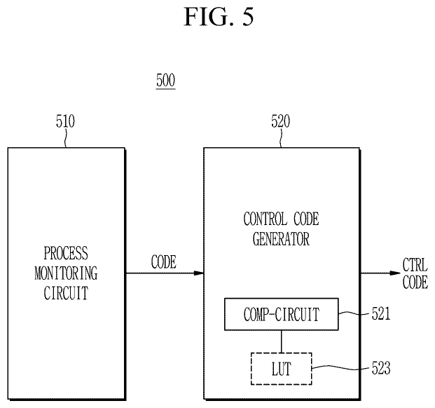

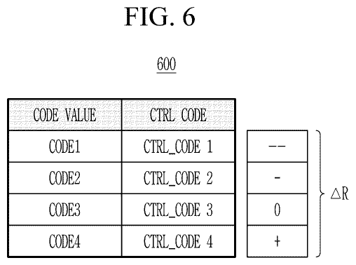

A configuration and an operation method of the control code generator 420 will be described later with reference to FIGS. 5 and 6.

FIG. 5 illustrates a block diagram showing a process monitoring module according to one or more embodiments. Specifically, this is a diagram for describing a control code generator 520 within a process monitoring module 500.

In one or more embodiments, the control code generator 520 may receive a code signal CODE from the process monitoring circuit 510. For example, the control code generator 520 may receive a delay code signal as the code signal CODE from a delay locked loop circuit in the process monitoring circuit 510, or may receive the ZQ code signal as the code signal CODE from the ZQ calibration circuit in the process monitoring circuit 510, but the present disclosure is not limited thereto.

In one or more embodiments, the control code generator 520 may generate a control code signal CTRL CODE for controlling a bias circuit 220 (in FIG. 2) that generates a reference current (or reference voltage) based on the code signal CODE. The control code signal CTRL CODE may be a value corresponding to the characteristics of the transistors inside the semiconductor device. The control code generator 520 may transmit the control code signal CTRL CODE to the bias circuit 220 such that the bias circuit 220 has characteristics that are insensitive to process variables.

In one or more embodiments, the control code generator 520 may include a comparison circuit 521. The comparison circuit 521 may determine characteristics of transistors inside the semiconductor device according to process variables based on the code signal CODE received from the process monitoring circuit 510. For example, the comparison circuit 521 may predetermine a reference code value that serves as a reference for determining characteristics of transistors inside the semiconductor device, and determine the characteristics of transistors inside the semiconductor device by comparing the code signal CODE and the reference code value.

In one or more embodiments, the comparison circuit 521 may output the control code signal CTRL CODE to adjust a value of the variable resistor in the bias circuit 220 based on the characteristics of the transistors inside the semiconductor device. For example, if the code signal CODE is smaller than the reference code value as a result of comparing the code signal CODE and the reference code value, it may be determined that a speed of the transistors inside the semiconductor device is slow, and the control code signal CTRL CODE may be output to reduce the value of the variable resistance in the bias circuit 220. Alternatively, if the code signal CODE is greater than the reference code value as a result of comparing the code signal CODE and the reference code value, it may be determined that a speed of the transistors inside the semiconductor device is fast, and the control code signal CTRL CODE may be output to increase the value of the variable resistance in the bias circuit 220.

In one or more embodiments, the control code generator 520 may further include a lookup table 523. The comparison circuit 521 may determine characteristics of transistors inside the semiconductor device according to process variables based on the code signal CODE received from the process monitoring circuit 510, and may output the control code signal CTRL CODE based on the lookup table 523. Specifically, the comparison circuit 521 may output the control code signal CTRL CODE such that the bias circuit 220 generates the reference current or reference voltage that reflects the characteristics of transistors within the semiconductor device based on the lookup table 523 having the control code signal CTRL CODE corresponding to the code signal CODE received from the process monitoring circuit 510. The lookup table 523 will be described in detail with reference to FIG. 6.

FIG. 6 illustrates a view for describing a lookup table according to one or more embodiments.

Referring to FIG. 6, in one or more embodiments, the lookup table 600 may store a code value CODE VALUE and a corresponding control code signal CTRL CODE. Herein, the code value CODE VALUE is a delay code signal or a ZQ code signal received from the process monitoring circuit 510, and may be a digital value.

In one or more embodiments, the comparison circuit 521 may predetermine a reference code value that serves as a reference to determine the characteristics of transistors within the semiconductor device. For example, a third code value CODE3 is a predetermined value that serves as a reference for determining characteristics of transistors inside the semiconductor device, and may be a value indicating that a speed of the transistors inside the semiconductor device is nominal. Accordingly, if the code value CODE VALUE is smaller than the third code value CODE3 (e.g., if it is the first code value CODE1 or the second code value CODE2, the comparison circuit 521 may determine that the speed of the transistors inside the semiconductor device is slow, and may select and output a control code signal (e.g., a first control code signal CTRL_CODE 1 or a second control code signal CTRL_CODE 2) corresponding to the code value. Alternatively, if the code value CODE VALUE is greater than the third code value CODE3 (e.g., if it is the fourth code value CODE4), the comparison circuit 521 may determine that the speed of the transistors inside the semiconductor device is fast, and may select and output a control code signal (e.g., the fourth control code signal CTRL_CODE 4) corresponding to the code value.

In one or more embodiments, the control code signal CTRL CODE is a code signal for adjusting a value of variable resistance of the bias circuit 220, and may be a digital value. For example, if the code value CODE VALUE received from the process monitoring circuit 510 is smaller than the reference code value CODE3, the comparison circuit 521 may select and output the control code signal CTRL CODE corresponding to the code value CODE VALUE such that variable resistance R of the bias circuit 220 decreases (i.e., the reference current Iref increases). Alternatively, if the code value CODE VALUE received from the process monitoring circuit 510 is greater than the reference code value CODE3, the comparison circuit 521 may select and output the control code signal CTRL CODE corresponding to the code value CODE VALUE such that the variable resistance R of the bias circuit 220 increases (i.e., the reference current Iref decreases). In one or more embodiments, as the code value CODE VALUE received from the process monitoring circuit 510 moves away from the reference code value CODE3, a change amount (AR) in the variable resistance may increase.

A semiconductor device according to one or more embodiments may change a value of the variable resistor in the bias circuit based on the control code signal depending on the process variable, making the bias circuit insensitive to process changes.

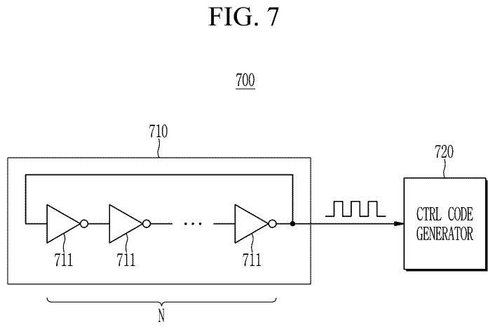

FIG. 7 illustrates a block diagram showing a process monitoring module according to one or more embodiments. Specifically, this diagram is for describing a ring oscillator 710 as an example of a process monitoring circuit within the process monitoring module 700.

Referring to FIG. 7, the process monitoring module 700 may include the ring oscillator 710 and a control code generator 720. The ring oscillator 710 is a structure in which a plurality of inverters 711 (e.g., N, where N is a natural number greater than 1) are connected in a closed loop, and an output voltage (or phase) of a random inverter is inverted and output by successive inverters, which is repeated infinitely. Accordingly, a frequency of an oscillator signal that can be obtained from an output terminal of one inverter forming a closed circuit may be determined by a number of inverters included in the ring oscillator 710 and a delay time of each inverter. When a time to generate an output signal in response to an input signal of the inverter 711 is referred to as the delay time of the inverter, characteristics of the transistors that constitute the inverter 711 change depending on the process variable, and thus a delay time of the inverter 711 changes, and this ultimately changes a pulse width of an oscillation signal.

In one or more embodiments, the control code generator 720 may receive an oscillating signal from the ring oscillator 710. The oscillation signal that the control code generator 720 receives from the ring oscillator 710 may include characteristic information of the inverter 711 based on the process variable. Since the characteristics of the transistors in the inverter 711 according to the process variable are substantially the same as the characteristics of the transistors in the semiconductor device, the control code generator 720 may generate a control code for controlling the bias circuit based on the oscillation signal received from the ring oscillator 710.

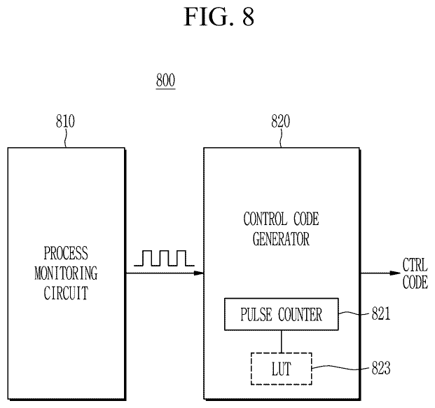

FIG. 8 illustrates a block diagram showing a process monitoring module according to one or more embodiments. Specifically, this is a diagram for describing a control code generator 820 within a process monitoring module 800.

In one or more embodiments, the control code generator 820 may receive an oscillating signal from the process monitoring circuit 810. For example, the control code generator 820 may receive an oscillation signal as an output signal of one inverter constituting a ring oscillator from the process monitoring circuit 810 implemented as the ring oscillator. The control code generator 820 may receive an oscillating signal from the process monitoring circuit 810 in an initial state. Herein, the initial state may refer to a period of time after a power is applied to the semiconductor device. However, the present disclosure is not limited thereto. Accordingly, the oscillating signal received by the control code generator 820 may be a value representing characteristic information of the semiconductor device caused by process variables excluding temperature changes and voltage fluctuations that may occur during operation of the semiconductor device.

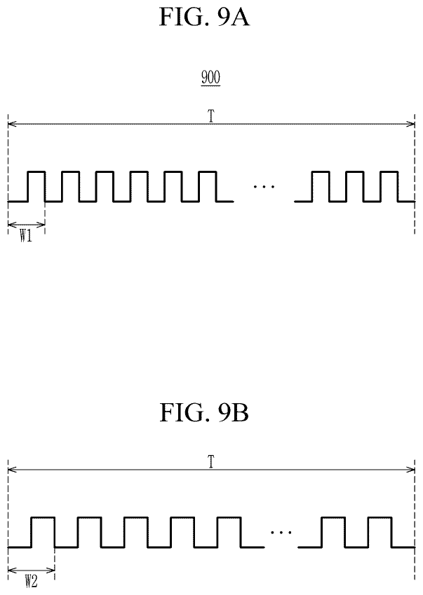

In one or more embodiments, the control code generator 820 may include a pulse counter 821 and a lookup table 823. The pulse counter 821 may count a number of pulses of the oscillating signal received from the process monitoring circuit 810 during a predetermined time period. An operating method of the pulse counter 821 will be described with reference to FIGS. 9A and 9B.

FIGS. 9A and 9B illustrate views for describing an operation method of a pulse counter according to one or more embodiments.

Referring to FIG. 7, as described above, a pulse width W of the oscillation signal output by the process monitoring circuit 810 implemented as a ring oscillator may vary depending on a delay time of the inverter constituting the ring oscillator, and the delay time of the inverter may vary depending on the characteristics of the process variables of the transistors that constitute the inverter. Accordingly, depending on the characteristics of the transistors constituting the inverter in the ring oscillator, a number of pulses of the oscillating signal output during a certain time T may be different.

FIG. 9A represents an oscillating signal whose pulse width is a first pulse width W1, and FIG. 9B represents an oscillating signal whose pulse width is a second pulse width W2, and the second pulse width W2 may be greater than the first pulse width W1.

In one or more embodiments, the pulse counter 821 may count a number of pulses of the oscillating signal received from the process monitoring circuit 810 during a predetermined time period T. Referring to FIGS. 9A and 9B, the first pulse width W1 and the second pulse width W2 are different, and thus a number of pulses of the oscillating signal that the pulse counter 821 counts during the predetermined time T may be different between an oscillating signal of the first pulse width W1 and an oscillating signal of the second pulse width W2. That is, for a number of pulses of the oscillating signal that the pulse counter 821 counts during the predetermined time T, the oscillating signal of the first pulse width W1 may be greater than the oscillating signal of the second pulse width W2.

In one or more embodiments, the pulse width W may represent characteristics of a transistor depending on the process variable. For example, a wide pulse width W may indicate that a delay speed of the transistors constituting the semiconductor device is large. Accordingly, the characteristic of the transistor outputting the first pulse width W1 may be fast, and the characteristic of the transistor outputting the second pulse width W2 may be slow.

In one or more embodiments, the pulse counter 821 may determine the characteristics of transistors inside the semiconductor device according to process changes based on the oscillating signal received from the process monitoring circuit 810, and may output the control code signal CTRL CODE corresponding to the characteristics of the transistors based on the lookup table 823. Specifically, the pulse counter 821 may determine and output the control code signal CTRL CODE such that the bias circuit 220 generates a reference current or a reference voltage that reflects the characteristics of transistors within the semiconductor device based on the lookup table 823 having the control code signal CTRL CODE corresponding to the number of pulses of the oscillating signal received from the process monitoring circuit 810.

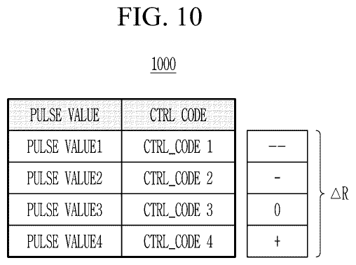

FIG. 10 illustrates a view for describing a lookup table according to one or more embodiments.

Referring to FIG. 10, in one or more embodiments, the lookup table 1000 may store the pulse value PULSE VALUE and the control code signal CTRL CODE corresponding thereto. Herein, the pulse value PULSE VALUE is a number of pulses of the oscillation signal received from the process monitoring circuit 810.

In one or more embodiments, the pulse counter 821 may predetermine a reference pulse value that serves as a reference to determine the characteristics of transistors within the semiconductor device. For example, a third pulse value PULSE VALUE3 is a predetermined value that serves as a reference for determining characteristics of transistors inside the semiconductor device, and may be a value indicating that a speed of the transistors inside the semiconductor device is nominal. Accordingly, if the pulse value PULSE VALUE is smaller than the third pulse value PULSE VALUE3 (e.g., if it is the first pulse value PULSE VALUE1 or the second pulse value PULSE VALUE2, the pulse counter 821 may determine that the speed of the transistors inside the semiconductor device is slow, and may select and output a control code signal (e.g., a first control code signal CTRL_CODE 1 or a second control code signal CTRL_CODE 2) corresponding to the pulse value. Alternatively, if the pulse value PULSE VALUE is greater than the third pulse value PULSE VALUE3 (e.g., if it is the fourth pulse value PULSE4), the pulse counter 821 may determine that the speed of the transistors inside the semiconductor device is fast, and may select and output a control code signal (e.g., the fourth control code signal CTRL_CODE 4) corresponding to the code value.

In one or more embodiments, the control code signal CTRL CODE is a code signal for adjusting a value of variable resistance of the bias circuit 220, and may be a digital value. For example, if the pulse value PULSE VALUE corresponding to a number of pulses of the oscillating signal received from the process monitoring circuit 810 is smaller than the reference pulse value PULSE VALUE3, the pulse counter 821 may select and output the control code signal CTRL CODE corresponding to the pulse value PULSE VALUE such that the variable resistance R of the bias circuit 220 decreases (i.e., the reference current Iref increases). Alternatively, if the pulse value PULSE VALUE corresponding to the number of pulses of the oscillating signal received from the process monitoring circuit 810 is greater than the reference pulse value PULSE VALUE3, pulse counter 821 may select and output the control code signal CTRL CODE corresponding to the pulse value PULSE VALUE such that the variable resistance R of the bias circuit 220 increases (that is, the reference current Iref decreases). In one or more embodiments, as the number of pulses of the oscillating signal received from the process monitoring circuit 810 moves away from the reference pulse value PULSE VALUE3, the amount of change (AR) in the variable resistance may increase.

A semiconductor device according to one or more embodiments may change a value of the variable resistor in the bias circuit based on the control code signal depending on the process variable, making the bias circuit insensitive to process changes.

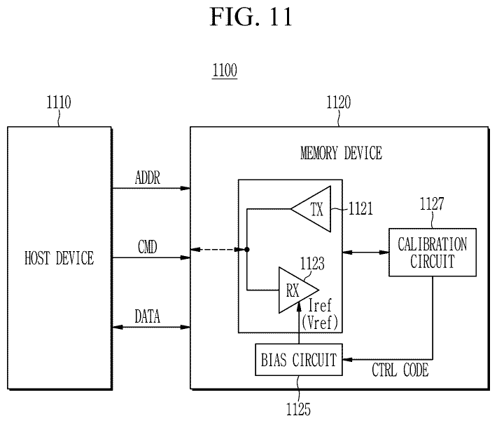

FIG. 11 illustrates a configuration of a semiconductor system according to one or more embodiments.

Referring to FIG. 11, the semiconductor system 1100 may include a first semiconductor device 1110 and a second semiconductor device 1120. The first semiconductor device 1110 may provide various control signals necessary for the second semiconductor device 1120 to operate. In one or more embodiments, the first semiconductor device 1110 may include various types of host devices. For example, the first semiconductor device 1110 may be a host device such as a central processing unit (CPU), a graphics processing unit (GPU), a multi-media processor (MMP), a digital signal processor, or an application processor (AP). In one or more embodiments, the second semiconductor device 1120 may be, e.g., a memory device, and the memory device may include a volatile memory and a non-volatile memory. For example, the volatile memory may include a static RAM (SRAM), a dynamic RAM (DRAM), and a synchronous DRAM (SDRAM), and Non-volatile memory may include a read only memory (ROM), a programmable ROM (PROM), an electrically erase and programmable ROM (EEPROM), an electrically programmable ROM (EPROM), a flash memory, a phase change RAM (PRAM), a magnetic RAM (MRAM), a resistive RAM (RRAM), and a ferroelectric RAM (FRAM).

The first semiconductor device 1110 may communicate with the second semiconductor device 1120 through various interfaces. For example, the first semiconductor device 1110 may communicate with the second semiconductor device 1120 through various interfaces such as a universal serial bus (USB), a multimediacard (MMC), PCIExpress (PCI-E), an AT attachment (ATA), a serial AT attachment (SATA), a parallel AT attachment (PATA), a small computer system interface (SCSI), a serial attached SCSI (SAS), an enhanced small disk interface (ESDI), an integrated drive electronics (IDE), and an non-volatile memory express (NVMe).

The first semiconductor device 1110 may provide control signals such as an address signal (ADDR) and an instruction signal (CMD) to the second semiconductor device 1120. Additionally, the first semiconductor device 1110 may exchange a data signal (DATA) with the second semiconductor device 1120.

In one or more embodiments, the second semiconductor device 1120 may include a transmission circuit (TX, 1121) and a reception circuit (RX, 1123). The transmission circuit 1121 may transmit a data signal (DATA) to the first semiconductor device 1110 based on an internal signal of the second semiconductor device 1120. The reception circuit 1123 may receive signals transmitted from the first semiconductor device 1110, and may generate signals used inside the second semiconductor device 1120 based on them.

In one or more embodiments, the second semiconductor device 1120 may include a calibration circuit 1127. The calibration circuit 1127 may include, but is not limited to, a delay loop circuit for generating a clock signal used inside the second semiconductor device 1120 or a ZQ calibration circuit for impedance matching inside the second semiconductor device 1120. In one or more embodiments, the calibration circuit 1127 may output a control code signal CTRL CODE to control the bias circuit 1125. The calibration circuit 1127 may detect characteristics of transistors in the second semiconductor device 1120, and may generate a control code signal CTRL CODE corresponding thereto. The control code signal CTRL CODE according to one or more embodiments is a value that reflects the characteristics of transistors in the semiconductor device according to process variation, and may be a digital value.

In one or more embodiments, the second semiconductor device 1120 may further include a bias circuit 1125. The bias circuit 1125 may generate a reference current Iref or a reference voltage Vref, and may supply the reference current Iref or the reference voltage Vref to the reception circuit 1123. The reception circuit 1123 may generate a signal used within the second semiconductor device 1120 based on the reference current Iref or the reference voltage Vref supplied from the bias circuit 1125. In one or more embodiments, the bias circuit 1125 may include a variable resistor that changes based on the control code signal CTRL CODE. The bias circuit 1125 may generate the reference current Iref or the reference voltage Vref that reflects the characteristics of transistors in the second semiconductor device 1120 based on changes in variable resistance. The bias circuit 1125 and the calibration circuit 1127 may be implemented as a bias circuit and a process monitoring module according to FIGS. 1 to 10. As a result, it is possible to prevent performance degradation of the semiconductor device due to process variables.

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

1. A semiconductor device comprising:
an amplifier circuit biased by a reference current or a reference voltage and configured to amplify an input signal;
a process monitoring circuit configured to output a control code signal to compensate a manufacturing process deviation of the semiconductor device; and
a bias circuit configured to receive the control code signal and to change the reference current or the reference voltage based on the control code signal.

2. The semiconductor device of claim 1, wherein the bias circuit comprises a variable resistor whose resistance value changes based on the control code signal to change the reference current or the reference voltage.

3. The semiconductor device of claim 2, wherein the process monitoring circuit comprises:
a process monitoring sub-circuit configured to generate a first code signal representing characteristics of the semiconductor device based on an operating speed of transistors of the semiconductor device; and
a control code generator configured to generate the control code signal corresponding to the first code signal and adjusting the resistance value of the variable resistor.

4. The semiconductor device of claim 3, wherein the process monitoring circuit is a delay locked loop circuit.

5. The semiconductor device of claim 3, wherein the control code generator is configured to:
compare the first code signal with a predetermined reference code value; and
output the control code signal corresponding to the first code signal and decreasing the resistance value of the variable resistor based on a value of the first code signal being smaller than the predetermined reference code value.

6. The semiconductor device of claim 3, wherein the control code generator further comprises a lookup table comprising the first code signal and the control code signal corresponding thereto.

7. The semiconductor device of claim 2, wherein the process monitoring circuit comprises:
a ring oscillator configured to generate an oscillating signal representing sensed characteristics of the semiconductor device; and
a control code generator configured to output the control code signal corresponding to the oscillating signal and adjusting the resistance value of the variable resistor.

8. The semiconductor device of claim 7, wherein the control code generator configured to:
count a number of pulses of the oscillating signal output from the ring oscillator for a predetermined time and output the control code signal based on a lookup table comprising the control code signal corresponding to the number of pulses.

9. The semiconductor device of claim 1, wherein the control code signal is a digital code signal.

10. The semiconductor device of claim 1, wherein the bias circuit is a beta multiplier reference circuit.

11. A semiconductor device comprising:
a process monitoring circuit configured to:
generate a first signal representing characteristic information based on the characteristic information obtained in an initial state, which is within a predetermined time after a power is applied; and
output a digital code signal corresponding to the first signal;
a bias circuit configured to generate a bias current or a bias voltage based on a value of a variable resistance changed based on the digital code signal; and
a device circuit configured to receive the bias current or the bias voltage.

12. The semiconductor device of claim 11, wherein the process monitoring circuit comprises:
a process monitoring sub-circuit configured to:
acquire characteristic information of the semiconductor device based on an operating speed of transistors of the semiconductor device in the initial state; and
generate the first signal; and
a control code generator configured to output the digital code signal corresponding to the first signal and adjusting the value of the variable resistance.

13. The semiconductor device of claim 12, wherein the control code generator further comprises a lookup table comprising a plurality of signal values representing characteristics of the semiconductor device and a plurality of digital code signals corresponding thereto.

14. The semiconductor device of claim 12, wherein the control code generator is configured to:
output a first digital code signal that increases the value of the variable resistance, among a plurality of digital code signals, based on a first signal indicating that the operating speed of the transistors is fast among a plurality of signals; and
output a second digital code signal that reduces the value of the variable resistance, among the plurality of digital code signals, based on a second signal indicating that the operating speed of the transistors is slow, among the plurality of signals.

15. The semiconductor device of claim 12, wherein the process monitoring circuit is a delay locked loop circuit.

16. The semiconductor device of claim 11, wherein the process monitoring circuit comprises:
a ring oscillator configured to generate an oscillating signal representing characteristic information of the semiconductor device; and
a control code generator configured to output the digital code signal corresponding to the oscillating signal and adjusting the value of the variable resistance.

17. The semiconductor device of claim 11, wherein the characteristic information comprises corner values of transistors of the semiconductor device.

18. The semiconductor device of claim 11, wherein the initial state is a time period from when the power is applied until a signal representing the characteristic information is output a predetermined number of times.

19. A semiconductor system comprising:
a first semiconductor device; and
a second semiconductor device comprising:
a receiving circuit configured to receive a signal from the first semiconductor device; and
a bias circuit configured to supply different reference currents or reference voltages to the receiving circuit based on a value of a variable resistor that changes in response to characteristics due to a manufacturing process deviation of the second semiconductor device.

20. The semiconductor system of claim 19, wherein the second semiconductor device further comprises a calibration circuit configured to detect characteristics of the second semiconductor device based on the manufacturing process deviation and supply a control code signal corresponding to the characteristics of the second semiconductor device to the bias circuit to change the value of the variable resistor.

21. (canceled)
